(19) United States
(12) Patent Application Publication
(10) Pub. No.: US 2024/0363374 A1
(43) Pub. Date: Oct. 31, 2024

(54) SYSTEM AND METHOD FOR SELECTIVE ETCHING OF AMORPHOUS SILICON OVER EPITAXIAL SILICON AT LOW SUBSTRATE TEMPERATURE

(71) Applicant: Applied Materials, Inc., Santa Clara, CA (US)

(72) Inventors: Mukhles SOWWAN, Sunnyvale, CA (US); Shu-Kwan LAU, Sunnyvale, CA (US)

(21) Appl. No.: 18/632,376

(22) Filed: Apr. 11, 2024

Related U.S. Application Data
(60) Provisional application No. 63/462,393, filed on Apr. 27, 2023.

(51) Int. Cl. H01L 21/67; C01B 33/02; C30B 29/06; C30B 33/12; H01L 21/3065

(52) U.S. Cl. CPC H01L 21/67069; C01B 33/02; C30B 29/06; C30B 33/12; H01L 21/3065

(57) ABSTRACT

Disclosed herein are a processing chamber, a radical generation cartridge, and a method for etching amorphous silicon selectively relative to crystalline silicon. In one example, the selective silicon etching process is performed in an epitaxy processing chamber. In an example, a processing chamber is provided that includes a chamber body, a transparent dome, a susceptor, a heat source, and a first hot wire filament. The transparent dome is disposed on the chamber body and with the body, partially enclosing a processing volume. The susceptor is disposed in the processing volume. The heat source is positioned to direct radiant energy through the transparent dome toward the susceptor. The first hot wire filament is disposed in a first gas inlet formed through the chamber body. The first hot wire filament is configured to generate radicals from gas flowing through the first gas inlet into the processing volume of the processing chamber.

### RELATED APPLICATIONS

This application claims benefit from U.S. Provisional Application Ser. No. 63/462,393, filed Apr. 27, 2023, which is incorporated herein by reference in its entirety.

### BACKGROUND

### Field

The present disclosure relates to components and epitaxial system that includes a filament for dissociating process gases, and more specifically to system and method for selectively etching amorphous silicon (a-Si) over epitaxial silicon (Si) and other materials at a low substrate temperature using disassociated hydrogen.

### Description of the Related Art

Epitaxy refers to processes used to grow a thin crystalline layer on a crystalline substrate (epi layer). Epitaxy is a method of vapor deposition and type of semiconductor manufacturing used to form devices on silicon wafers. The epi layer on a semiconductor substrate can improve the electrical characteristics of the surface and make the substrate and the surface suitable for highly complex microprocessors and memory devices.

Selectively etching amorphous silicon (a-Si) over crystalline silicon (c-Si) is a method used in growth of epitaxial layers for forming semiconductor devices on silicon wafers. High temperatures can damage materials in Epi chambers, including the underlying layers of the substrate. Low temperature dry etching is preferred in order to reduce thermal damage to the substrate, reduce processing times, and reduce the overall cost of processing. Selectively etching of a-Si at temperatures lower than 500° C. is important in processing and fabricating advanced logic devices and integrated circuits in an Epi chamber. Conventional Epi chambers often use chlorine (Cl) based Si etchants, however, dry etching of a-Si can also be achieved using atomic hydrogen. However, atomic hydrogen recombines quickly and state of the art Epi chambers are currently not configured for effective use of hydrogen as an etchant.

Thus, a need exists for an improved substrate processing system for selectively etching a-Si at low temperatures.

### SUMMARY

Disclosed herein are a processing chamber, a radical generation cartridge, and a method for etching amorphous silicon selectively relative to crystalline silicon. In one example, the selective silicon etching process is performed in an epitaxy processing chamber. In an example, a processing chamber is provided that includes a chamber body, a transparent dome, a susceptor, a heat source, and a first hot wire filament. The transparent dome is disposed on the chamber body and with the body, partially enclosing a processing volume. The susceptor is disposed in the processing volume. The heat source is positioned to direct radiant energy through the transparent dome toward the susceptor. The first hot wire filament is disposed in a first gas inlet formed through the chamber body. The first hot wire filament is configured to generate radicals from gas flowing through the first gas inlet into the processing volume of the processing chamber.

In some examples, the first hot wire filament is disposed a first cartridge that is replaceably insertable into the first gas inlet of the chamber body. The first cartridge may include gas port coupled to a gas channel. The gas port is exposed to an exterior of the chamber body, while the gas channel configured to direct the gas flowing through first gas port across the first hot wire filament and into the processing volume.

In some examples, the first cartridge includes a first electrical connector electrically coupled to the first hot wire filament. The first electrical connector is also exposed to the exterior of the chamber body.

In some examples, a first primary gas port formed through the chamber body. The first primary gas port is disposed at a distance relative to the dome that is different a distance that the first gas inlet is disposed from the dome. The first primary gas port and the first gas inlet may be coupled to different gas sources or to a common gas source.

In yet another example, a processing chamber is provided that includes a chamber body, a transparent dome, a susceptor, a heat source, and a hot wire filament array. The transparent dome is disposed on the chamber body and with the body, partially enclosing a processing volume. The susceptor is disposed in the processing volume. The heat source is positioned to direct radiant energy through the transparent dome toward the susceptor. The hot wire filament array is disposed within the processing volume between the susceptor and the dome. The first hot wire filament is configured to heat gas flowing from the first gas inlet within the processing volume of the processing chamber.

In some examples, the hot wire filament array has an orientation substantially parallel to an orientation of the susceptor.

In some examples, the hot wire filament array includes wires arranged in a grid.

In some examples, the hot wire filament array and the first gas inlet are spaced at a common elevation relative to a top surface of the chamber body.

In some examples, a first primary gas port is formed through the chamber body at a distance relative to the dome that is different a distance that the first gas inlet is disposed from the dome.

In some examples, the first primary gas port and the first gas inlet are coupled to different gas sources.

In some examples, the first primary gas port and the first gas inlet are coupled to a common gas source, wherein a ratio of gas provided to the first primary gas port and the first gas inlet is controllable.

In still another example, a method for selectively etching a substrate is provided that includes directing radiant energy through a transparent dome to a substrate disposed on a susceptor disposed in a processing volume defined in a processing chamber; maintaining a temperature of the substrate disposed on the susceptor below 500 degrees Celsius; creating hydrogen radicals from a hydrogen containing gas flowing across one or more hot wire filaments; and selectively etching a-Si relative to c-Si disposed on the substrate within the processing volume using the hydrogen radicals.

In some examples, creating hydrogen radicals further includes forming creating hydrogen radicals within a cartridge coupled to a sidewall of the processing chamber.

In some examples, creating hydrogen radicals further includes forming creating hydrogen radicals above the susceptor within the processing volume.

In some examples, the method further includes flowing a gas used to create the hydrogen radicals and a main processing gas into the processing chamber from inlets disposed at different elevations relative to the susceptor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic top view of a processing system, according to an embodiment of the present application

FIG. 2 is a schematic cross-sectional view of an EPI processing chamber, according to an embodiment of the present application.

FIG. 3 is a schematic cross-sectional view of a portion of a chamber body of the EPI processing chamber of FIG. 2, according to an embodiment of the present application.

FIG. 4 is a schematic cross-sectional view of a portion of a chamber body of the EPI processing chamber of FIG. 2, according to another embodiment of the present application.

FIG. 5 is a schematic cross-sectional view of a portion of a chamber body of the EPI processing chamber of FIG. 2, according to another embodiment of the present application.

FIG. 6 is partial sectional view of a portion of a hot wire filament array that can be optionally utilized in the processing chamber of FIG. 2, according to an embodiment of the present application.

FIG. 7 is a partial sectional view of a portion of a hot wire filament array that can be optionally utilized in the processing chamber of FIG. 2, according to an embodiment of the present application.

FIG. 8 is a schematic cross-sectional view of a portion of a chamber body of the EPI processing chamber of FIG. 2, according to an embodiment of the present application.

FIG. 9 is a flow diagram of a method for selectively etching amorphous silicon in a processing chamber, according to an embodiment of the present application.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Disclosed herein are a processing chamber, a radical generation cartridge, and a method for dry etching amorphous silicon selectively relative to crystalline silicon. The apparatus and method both utilize atomic hydrogen radicals as an etchant generated using a hot-wire filament disposed in the gas inlet, or the interior of an Epi chamber, or other suitable processing chamber. For some substrate manufacturing processes, performing an etch process within an Epi chamber is desirable due to ability to precisely control substrate temperatures via radiant heating, and/or the ability to also perform epitaxial processes in-situ the same processing chamber. In one example, a hydrogen containing gas is exposed to a hot wire filament, with the filament dissociating the hydrogen from the molecular gas into atomic hydrogen. The atomic hydrogen is then used to etch a-Si selectively over c-Si. The method and apparatus advantageously enables molecular hydrogen to be dissociated into atomic hydrogen very close to the substrate, thus reducing recombination. Moreover, the hot wire filament does not substantially heat the substrate, all allowing low temperature (e.g., temperatures less than 500 degrees Celsius) to be maintaining in the Epi chamber.

When a semiconductor substrate is heated in the Epi chamber during a substrate processing, maintaining uniform temperatures across the surface of a semiconductor substrate can be challenging. Temperature is an important factor impacting deposition rate, crystal structure, and doping, and this a large temperature gradient can cause the Epi layer to have relatively large variations in terms of thickness and electrical resistivity throughout the substrate, or cause thermal damage to underlying layers. Dry etching of a-Si at a low temperature can be achieved using atomic hydrogen to break Si—Si bonds. The atomic hydrogen radicals etches a-Si faster than c-Si, that is the atomic hydrogen is selective to a-Si over c-Si. Further, boron doping can be used to decrease the etch rate of c-Si relative to the etch rate of a-Si. Thus, Si etching can be also selectively controlled using boron dopant.

According to an embodiment of the present application, a hot wire filament is configured disposed in a gas inlet. For example, the hot wire filament may be disposed in a replaceable cartridge inserted into the gas inlet.

In other examples, the hot wire filament may be part of a hot wire filament array. The hot wire filament array is disposed within the Epi chamber, affixed to the main body of the chamber above the susceptor. A carrier gas containing at least molecular hydrogen is flowed into the chamber such that the molecular hydrogen comes into contact with the filament array disposed in the Epi chamber.

According to a general aspect of the present application, a carrier gas mixed with a hydrogen containing gas is injected into the Epi chamber via a gas inlet. The hydrogen containing gas may be molecular hydrogen (H₂) or other suitable hydrogen source gas. The molecular hydrogen (H₂) is flowed across the filament according to the various embodiments disclosed herein and heated to a temperature sufficient to dissociate the molecular hydrogen (H₂) into atomic hydrogen (e.g., hydrogen radicals), but without significantly increasing the ambient temperature of the Epi chamber or the substrate. The atomic hydrogen is then used to processes the substrate by selectively etching the amorphous silicon a-Si over the crystalline silicon c-Si, without affecting the materials inside of the Epi chamber such as metals, quartz, and oxides, or exceeding the thermal budget of the device being formed on the substrate.

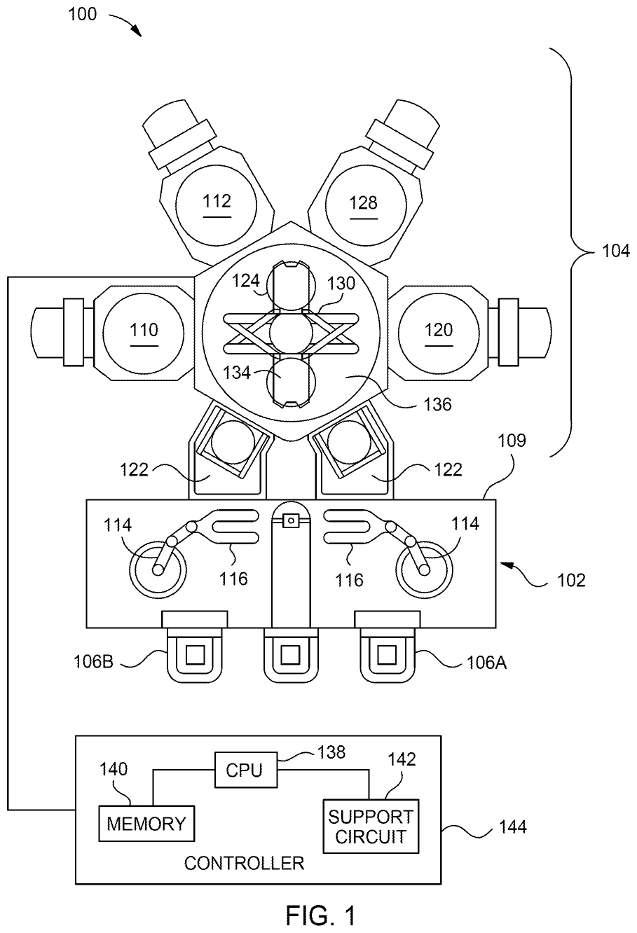

Turning now to FIG. 1, FIG. 1 illustrates a schematic top view of a processing system 100, according to one or more embodiments. The processing system 100 includes one or more load lock chambers 122 (two are shown in FIG. 1), a processing platform 104, a factory interface 102, and a controller 144. In one or more embodiments, the processing system 100 is a CENTURA® integrated processing system, commercially available from Applied Materials, Inc., located in Santa Clara, California. It is contemplated that other processing systems (including those from other manufacturers) may be adapted to benefit from the disclosure.

The platform 104 includes a plurality of processing chambers 110, 112, 120, 128, and the one or more load lock chambers 122 that are coupled to a transfer chamber 136. The transfer chamber 136 can be maintained under vacuum, or can be maintained at an ambient (e.g., atmospheric) pressure. Two load lock chambers 122 are shown in FIG. 1. The factory interface 102 is coupled to the transfer chamber 136 through the load lock chambers 122.

In one or more embodiments, the factory interface 102 includes at least one docking station 109 and at least one factory interface robot 114 to facilitate the transfer of substrates. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

Each of the load lock chambers 122 has a first port interfacing with the factory interface 102 and a second port interfacing with the transfer chamber 136. The load lock chambers 122 are coupled to a pressure control system (not shown) which pumps down and vents the load lock chambers 122 to facilitate passing the substrates between the environment (e.g., vacuum environment or ambient environment, such as atmospheric environment) of the transfer chamber 136 and a substantially ambient (e.g., atmospheric) environment of the factory interface 102.

The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, 128.

The controller 144 is coupled to the processing system 100 and is used to control processes and methods, such as the operations of the methods described herein (for example the operations of the method 1000 and/or the method 1050 described below). The controller 144 includes a central processing unit (CPU) 138, a memory 140 containing instructions, and support circuits 142 for the CPU. The controller 144 controls various items directly, or via other computers and/or controllers.

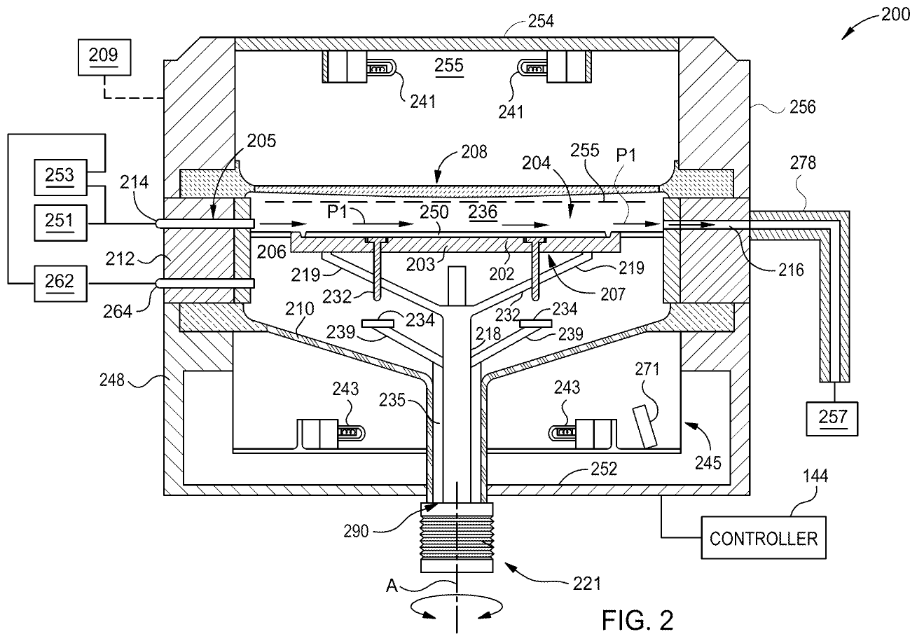

FIG. 2 illustrates a schematic cross-sectional view of an Epi processing chamber 200 according to an embodiment. The Epi processing chamber 200 is a deposition chamber to grow an Epi layer on a substrate 202. The processing chamber 200 represents one or more of the processing chambers 110, 112, 128 shown in FIG. 1. In one or more embodiments, a processing chamber 120 conducts processing (such as pre-cleaning or etching) at a temperature (such as an ambient temperature, for example a room temperature) that is lower than a processing temperature used in the processing chamber 200. A controller 144 is in communication with the processing chamber 200 and is used to control processes performed in, and function of, the processing chamber 200. The controller 144 may be the same or different than the controller 144 illustrated in FIG. 1.

The processing chamber 200 includes an upper body 256, a lower body 248 disposed below the upper body 256, and a chamber body 212 disposed between the upper body 256 and the lower body 248. An upper window 208 (such as an upper dome) and a lower window 210 (such as a lower dome) are disposed on the upper and lower surfaces of the chamber body 212 to enclose a processing volume 204. The windows 208, 210 are generally substantially transparent to radiant energy. A susceptor 203 is disposed in the processing volume 204 and configured to support a substrate 202 thereon during processing.

A plurality of upper heat sources 241 are disposed in the upper body 256 above the upper window 208 and below a lid 254 enclosing the upper body 256. The plurality of upper heat sources 241 are configured to direct radiant energy through the upper window 208 toward the susceptor 203 and a top surface 250 of the substrate 202 disposed thereon. Similarly, a plurality of lower heat sources 243 are disposed below the lower window 210. The plurality of lower heat sources 243 are configured to direct radiant energy through the lower window 210 toward the bottom of the susceptor 203.

According to an embodiment, the heat sources 241, 243 are lamps that are capable of generating infrared radiation. Other heat sources that are capable of generating infrared radiation are contemplated, such as resistive heaters, light emitting diodes (LEDs), and/or lasers.

The plurality of lower heat sources 243 are disposed between the lower window 210 and a chamber floor 252. The plurality of lower heat sources 243 form a portion of a lower heating module 245. The upper window 208 is an upper dome and is formed at least partially of an energy transmissive material, such as quartz. The lower window 210 is a lower dome and is formed at least partially of an energy transmissive material, such as quartz.

The processing chamber 200 includes one or more thermal sensors 271 configured to detect a thermal condition of the processing chamber 200. In one or more embodiments, the one or more thermal sensors 271 may include one or more cameras, one or more pyrometers, one or more thermoelectric sensors, and/or one or more thermal labels. The one or more thermal sensors 271 can be mounted, for example, below the lower window 210 (as shown in FIG. 2), or above the upper window 208 (such as on or in the lid 254), or any other suitable place in the processing chamber 200. According to an embodiment, a pyrometer is mounted below the lower window 210 and is configured to remotely measure temperature of the substrate 202 during the growth process of an Epi layer or during etching.

The susceptor 203 is support in the processing chamber by a plurality of arms 239 coupled to an inner shaft 218. The inner shaft 218 is coupled to a motion assembly 221 includes one or more actuators and/or motors that provide vertical and/or rotational movement of the inner shaft 218, which, in turn, moves susceptor 203 and the substrate 202 disposed thereon. Lift pin holes 207 are formed through the susceptor 203 and are each sized to accommodate lift pins 232 that is used to lift the substrate 202 during substrate transfer into and out of the chamber body 212 through a slit valve not shown in FIG. 1. An outer shaft 235 surrounds a portion of the inner shaft 218. The outer shaft 235 has a plurality of arms 239, each arm 239 terminating at a lift pins stop 234. The relative elevation of the outer shaft 235 and inner shaft 218 may be changed to cause the lift pins stop 234 to displace the lift pins 232 through the susceptor 203, thus lifting the substrate 202 above the susceptor 203 to allow access by a robot blade (not shown) that moves the substrate 202 into and out of the processing chamber 200.

The chamber body 212 includes a plurality of gas inlets 214, a plurality of purge gas inlets 264, and one or more gas exhaust outlets 216. The plurality of gas inlets 214 are generally aligned at a common elevation within the processing chamber 200, for example at a common distance from a top surface of the chamber body 212. The gas inlets 214 are connected with a plurality of process gas sources 251, 253 and provides a cross-flow of processing gases across the top surface 250 of the substrate 202. In some embodiments of the present application, some or all of the gas inlets 214 includes a hot wire filament 205. The process gas source 251 generally provides a hydrogen containing gas, such as H₂ and the like. The process gases supplied using the plurality of process gas sources 251, 253 can include one or more reactive gases (such as one or more of silicon (Si), phosphorus (P), and/or germanium (Ge)) and/or one or more carrier gases (such as one or more of nitrogen (N₂) and/or hydrogen (H₂)). The process gas source 251 may alternatively provide another type of gas disassociatable by a hot wire filament. The process gas source 253 generally provides processing gas and/or a carrier gas. The processing gas provided by the process gas source 253 may be the same as or different than the process gas provided by the process gas source 251. In one example, the carrier gas provided by the process gas source 253 is mixed with processing gas provided by the process gas source 251 prior to delivery to the gas inlets 214. The purge gas inlets 264 are connected with a purge gas source 262 and provide purge gas to the EPI processing chamber 200. The one or more purge gases supplied using the one or more purge gas sources 262 can include one or more inert gases (such as one or more of argon (Ar), helium (He), and/or nitrogen (N₂)). In one or more embodiments, the process gases may include silicon phosphide (SiP) and/or phosphine (PH₃).

The plurality of gas inlets 214 and the plurality of purge gas inlets 264 are disposed on the opposite side of the chamber body 212 from the one or more gas exhaust outlets 216. In one example, the plurality of gas inlets 214 are disposed at an elevation above the susceptor 203. The one or more gas exhaust outlets 216 are connected an exhaust conduit 278. The exhaust conduit 278 fluidly connects the one or more gas exhaust outlets 216 formed through the chamber body 212 to an exhaust pump 257 that evacuates the processing volume 204 and gases flowing into the processing volume 204 from at least the gas inlets 214.

The hot wire filament 205 is generally disposed in a location within the gas inlet 214 where gas flowing through the inlet may be disassociated prior to entering the processing volume 204. To better prevent recombination of the disassociated processing gases, the hot wire filament 205 may be preferentially located closer to the processing volume 204 than an exterior of the chamber body 212. The hot wire filament 205 is coupled to a power source 209 that controls the power provided to the filament 205.

In one example, power is provided from the power source 209 to heat the hot wire filament 205 to temperatures greater than 1500° C. in order to dissociate molecular hydrogen into atomic hydrogen. For example, the hot wire filament 205 may be heated to between 1500° C. to 2400° C. In an exemplary embodiment, the hot wire filament 205 is heated to 1850° C. The hot wire filament 205 can be made of materials such as tungsten (W) or carbon (C). The hot wire filament 205 may be subjected to a range of materials which may be corrosive. In some embodiments, the hot wire filament 205 is coated with corrosive resistant materials. Some examples of corrosive resistant materials that may be used to coat the hot wire filament 205 include boron nitride (BN) or silicon dioxide (SiO₂), among others. The hot wire filament 205 has a sufficiently thin diameter dissociate molecular hydrogen into atomic hydrogen without deferentially impacting the temperature of the substrate 202 and/or processing chamber 200. The hot wire filament 205 may have a diameter in a range of about 100 μm to about 2.5 mm. In an exemplary embodiment, the hot wire filament 205 has a diameter of about 250 μm. The hot wire filament 205 may also be made of other materials sufficient to meet the required conditions described herein. The hot wire filament 205 may also be coated with a range of other corrosive resistant materials not specifically disclosed herein.

The hot wire filament 205 may also be used to dissociate precursor molecules for the growth of Epi Si and silicon-germanium (SiGe) based materials. In some embodiments, precursor molecules can include SiH₄, Si₂H₆, Si₂H₂Cl₂, or other high order silane and germane precursors.

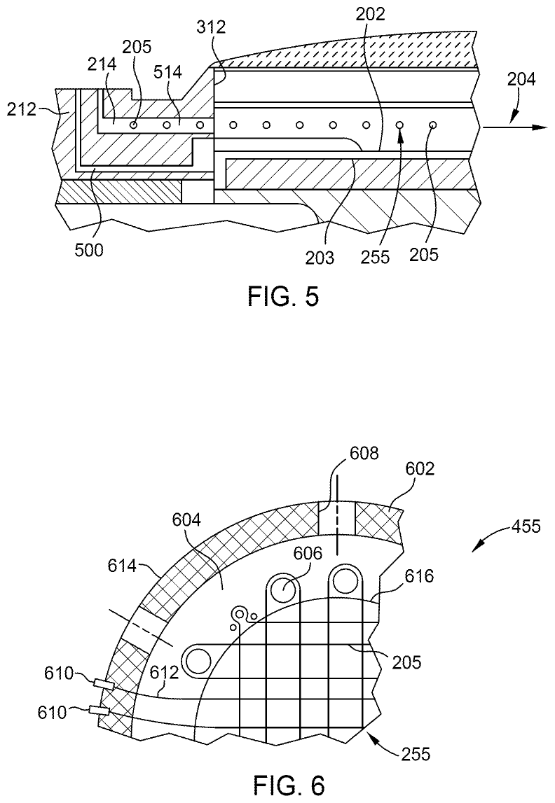

Alternatively, or in addition to the hot wire filaments 205 disposed in the gas inlets 214, a hot wire filament array 255 comprised of a plurality of hot wire filament 205 may be disposed in the processing volume 204 between the susceptor 203 and the upper window 208. The hot wire filament array 255 may be secured by a frame (shown in FIGS. 4 and 5) to the chamber body 212, or other portion of the processing chamber 200. In one example, the hot wire filament array 255 may be between 15 mm to 30 mm or more above the susceptor 203.

The hot wire filament array 255 may be centered within the processing chamber 200, or disposed closer to the inlet ports 214 relative to the one or more gas exhaust outlets 216 to reduce the potential for recombination of radicals produced by the hot wire filaments 205 of the hot wire filament array 255. The hot wire filaments 205 of the hot wire filament array 255 are also coupled to the power source 209. The hot wire filaments 205 of the hot wire filament array 255 may be arranged in a grid, such as in rows and columns, or other suitable arrangement. In another example, some or all of the hot wire filaments 205 of the hot wire filament array 255 are arranged at a non-zero angle (i.e., are not parallel) to a flow direction within the chamber volume defined between the gas inlet 214 and the exhaust outlets 216, which in one example is 90 degrees.

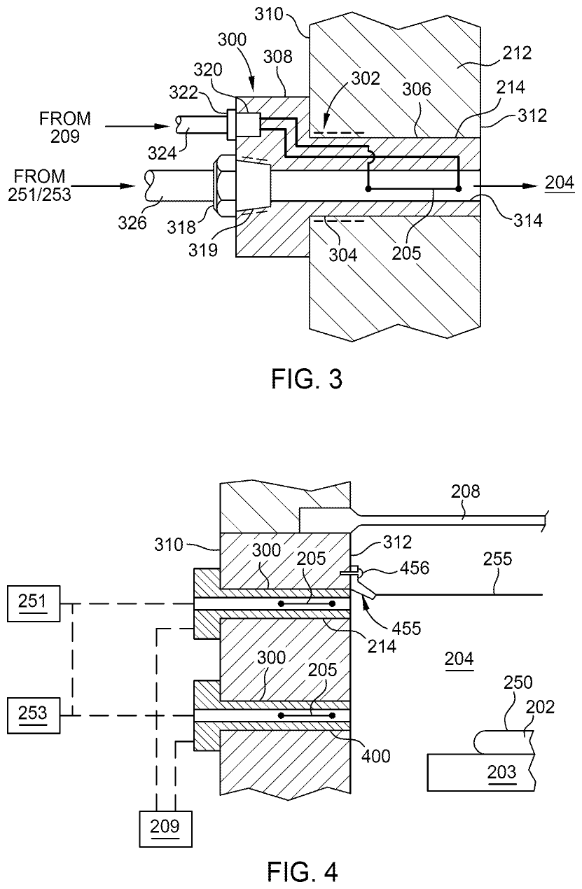

FIG. 3 illustrates a schematic cross-sectional view of a portion of the chamber body 212, according to an embodiment of the present application. The chamber body 212 has a ring shape with an inner wall 312 exposed to the processing volume 204, and an outer wall 310 exposed to the exterior of the chamber body 212. The gas inlet 214 is formed through the chamber body 212 exiting the walls 310, 312.

A hot wire filament cartridge 300 is disposed in the gas inlet 214. The hot wire filament cartridge 300 may be secured to the chamber body 212 via clamps, fasteners or other suitable technique. In the example depicted in FIG. 3, the cartridge 300 includes a male threaded portion 304 that engages a female threaded portion 302 of the gas inlet 214.

The cartridge 300 includes an elongated portion 306 and a head 308. The head 308 abuts the outer wall 310 of the chamber body 212 when the cartridge 300 is fully installed in the chamber body 212. An o-ring or other gasket (not shown) may be disposed between the cartridge 300 and the chamber body 212 to provide a vacuum seal therebetween.

A central passage 314 extends through the elongated portion 306 and the head 308 of the cartridge 300. One end of the central passage 314 is open to the processing volume 204. The other end of the central passage 314 has a port 316. The port 316 is configured to accept a fitting 318 that coupled the cartridge 300 via a conduit 326 to one or both of the gas sources 251, 253. In this manner, gas from one or both of the gas sources 251, 253 may be delivered through the passage 314 into the processing volume 204.

The hot wire filament 205 is disposed in the passage 314 of the cartridge 300. The hot wire filament 205 is connected to an electrical connector 320 that is also connected to the cartridge 300. The electrical connector 320, such as a socket or banana plug, is configured to receive a complimentary mating electrical connector 322. The electrical connector 322 is connect by one or more leads 324 to the power source 209. Thus, the power source 209 is able to power of the hot wire filament 205 disposed in the passage 314 of the cartridge 300.

As the gas flows through the passage 314 of the cartridge 300, the hot wire filament 205 is operable to disassociate at least some of the gases flowing into the processing volume 204 through the cartridge 300. In one example, a hydrogen containing gas, such as H₂, is flowed over the hot wire filament 205 disposed in the cartridge 300 such that hydrogen radicals are introduced into the processing volume 204. As depicted in FIG. 3, the hot wire filament 205 is disposed closer to the inter wall 312 than the outer wall 310 to reduce the probability of recombination of the disassociated hydrogen radicals prior to reaching the substrate 202.

As the fitting 318 and connector 322 allow the cartridge 300 to be easily disconnected from the sources 209, 251, 253, the cartridge 300 can be readily replaced.

FIG. 4 illustrates a schematic cross-sectional a portion of the chamber body 212, according to another embodiment of the present application. The chamber body 212 illustrated in FIG. 4 may be utilized in place of the chamber body 212 illustrated in FIG. 3 as part of the processing chamber 200 of FIG. 2. The chamber body 212 of FIG. 4 is essentially the same as the chamber body 212 illustrated in FIG. 3 except that the gas sources 251, 253 are coupled to the processing volume 204 not only through the gas inlet 214 formed through the chamber body 212, but additionally through one or more primary gas ports 400 formed through the chamber body 212. The primary gas port 400 disposed at a distance relative to the upper window 208 and the susceptor 203 that is different a distance that the gas inlet 214 is disposed from the upper window 208 and the susceptor 203 formed through the chamber body 212. In the example depicted in FIG. 4, the primary gas port 400 is farther from the upper window 208 and closer to the susceptor 203 than the gas inlet 214.

In one example, the gas inlet 214 is substantially aligned with, i.e., disposed at the elevation, as an optional hot wire filament array 255. The hot wire filament array 255 is secured by a frame 455 to the chamber body 212, in one example, by fasteners 456 secured to the chamber body 212. When the optional hot wire filament array 255 is utilized, the cartridges 300 become optional. The cartridges 300 may disposed in one or both of the primary gas port 400 and the gas inlet 214. When the optional hot wire filament array 255 is not present, the cartridges 300 may disposed in one or both of the primary gas port 400 and the gas inlet 214.

In one example, the primary gas port 400 and the gas inlet 214 are coupled to the same gas sources 251, 253. In another example, the primary gas port 400 is coupled to the processing gas source 253, while the gas inlet 214 is coupled to the processing gas source 251 such that the hydrogen containing as is directed in contact with the hot wire filament 205 disposed in the cartridge 300 and/or the hot wire filament array 255.

In some examples, the ratio of gases provided to the primary gas port 400 and the gas inlet 214 is different. In one instance, an amount of hydrogen containing gas within processing gas provide to the primary gas port 400 is greater than an amount of hydrogen containing gas within processing gas provided to the gas inlet 214. In another instance, an amount of hydrogen containing gas within processing gas provide to the primary gas port 400 is less than an amount of hydrogen containing gas within processing gas provided to the gas inlet 214.

FIG. 5 is a schematic cross-sectional view of a portion of a chamber body of the EPI processing chamber of FIG. 2, according to another embodiment of the present application. The chamber body 212 illustrated in FIG. 5 may be utilized in place of the chamber body 212 illustrated in FIG. 3 as part of the processing chamber 200 of FIG. 2. The chamber body 212 of FIG. 5 is essentially the same as the chamber body 212 illustrated in FIG. 3 except that the hot wire filament 205 is disposed in the passage 514 of the cartridge 500 in gas inlet 214 and also in the processing volume 204.

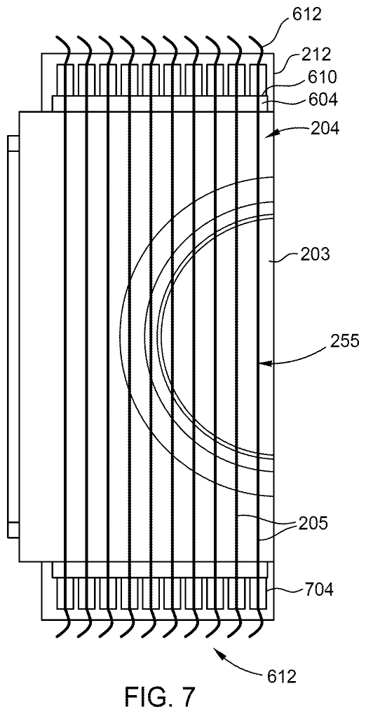

In some examples the hot wire filament 205 is one continuous filament from the gas inlet 214 through the processing volume 204. In some examples there are multiple hot wire filaments 205 disposed in the gas inlet 214 and in the processing volume 204. In yet another example, the hot wire filaments 205 in the processing volume 204 comprises a hot wire filament array 255. The hot wire filaments 205 in a hot wire filament array 255 may be connected together a single wire or to a single power supply node so that the hot wire filaments 205 of the hot wire filament array 255 a commonly controlled, for example, by applying the same power/current. Alternatively, the hot wire filament array 255 may be comprises of a plurality of independently controllable the hot wire filaments 205, for example, such that the power/current provided at least two hot wire filaments 205 is different. A single hot wire filament 205 disposed in an inlet cartridge may be combined with a hot wire filament array 255. In some examples, the hot wire filament is arranged in the manner shown in FIG. 6 or FIG. 7.

FIG. 6 is partial sectional view of a portion of the hot wire filament array 255 that can be optionally utilized in the processing chamber of FIG. 2, according to an embodiment of the present application. The frame 455 has a hoop 602 that includes a plurality of mounting holes 608 to through which the fasteners 456 (shown in FIG. 4) pass to secure the hoop 602 to the chamber body 212. A ring-shaped mounting flange 604 extends radially inward from the hoop 602 to an inside diameter cylindrical wall 616. The mounting flange 604 includes a plurality of guides 606, such as posts or hooks, around which the one or more hot wire filaments 205 of the hot wire filament array 255 are routed, thereby securing the hot wire filament array 255 to the frame 255 in a predefined pattern.

The one or more hot wire filaments 205 of the hot wire filament array 255 terminate at spring contacts 610 exposed on a cylindrical outer sidewall 614 of the mounting flange 604. The spring contacts 610 are coupled to the hot wire filaments 205 via leads 612. The spring contacts 610 may be pads, detent balls, pogo pins or other suitable electrical contacts for connecting the hot wire filaments 205 of the hot wire filament array 255 to the power source 209 through the chamber body 212 or other portion of the processing chamber 200.

FIG. 7 is partial sectional view of a portion of the hot wire filament array 255 that can be optionally utilized in the processing chamber of FIG. 2, according to an embodiment of the present application. In the example shown in FIG. 7, the hot wire filament array 255 is comprised of a plurality of hot wire filaments 205 arranged in parallel lines (alternative to the grid shown in FIG. 6). In an example, each of the plurality of hot wire filaments 205 of the hot wire filament array 255 is orientated in the same direction. In some examples the direction of the hot wire filament array 255 is orientated in parallel to the direction of the gas flow through the processing volume 204. In other examples, the hot wire filament array 255 is orientated perpendicular to the direction of the gas flow through the processing volume 204. In yet another example, the hot wire filament array 255 may be orientated at an angle between 0 and 180° with respect to the direction of the gas flow through the processing volume 204.

Each of the plurality of hot wire filaments 205 of the hot wire filament array 255 may be evenly spaced throughout the processing chamber. In some examples the plurality of hot wire filaments 205 of the hot wire filament array 255 may have uneven spacing throughout the processing chamber. For example, the plurality of hot wire filaments 205 may be more densely space closer to the gas inlet 214. In yet another example, the plurality of hot wire filaments 205 of the hot wire filament array 255 may be disposed directly over the substrate 202. In another example the plurality of hot wire filaments 205 of the hot wire filament array 255 may be disposed closer to the gas inlet 214. Alternative examples may exist that comprise a combination of one or more of the examples discussed, such as even spacing of the plurality of hot wire filaments 205 disposed near the gas inlet 214, or uneven spacing of the plurality of hot wire filaments 205 disposed over the substrate 202.

The hot wire filaments 205 of the hot wire filament array 255 may be mounted in a similar manner to the hot wire filament array 255 of FIG. 6, via a mounting flange 604 which includes a plurality of guides, such as posts or hooks, around which the one or more hot wire filaments 205 of the hot wire filament array 255 are routed, thereby securing the hot wire filament array 255 to the frame. Each of the plurality of hot wire filaments 205 of the hot wire filament array 255 may alternatively be mounted to the processing chamber via one or more sealing connectors 704. The one or more sealing connectors 704 may connect the plurality of hot wire filaments 205 to the power source 209. In some examples the temperature of each of the plurality of hot wire filaments 205 of the hot wire filament array 255 may be individually controllable, for example, by providing more or less current from the power source 209. In some examples, one or more of the plurality of hot wire filaments 205 have the same temperature (or current provided from the power source 209) while one or more other hot wire filaments 205 of the hot wire filament array 255 have a different temperature (or current provided from the power source 209).

The one or more hot wire filaments 205 of the hot wire filament array 255 may terminate at spring contacts 610 exposed on a cylindrical outer sidewall 614 of the mounting flange 604 or affixed to the sealing connectors 704. The spring contacts 610 are coupled to the hot wire filaments 205 via leads 612. The spring contacts 610 may be pads, detent balls, pogo pins or other suitable electrical contacts for connecting the hot wire filaments 205 of the hot wire filament array 255 to the power source 209 through the chamber body 212 or other portion of the processing chamber 200.

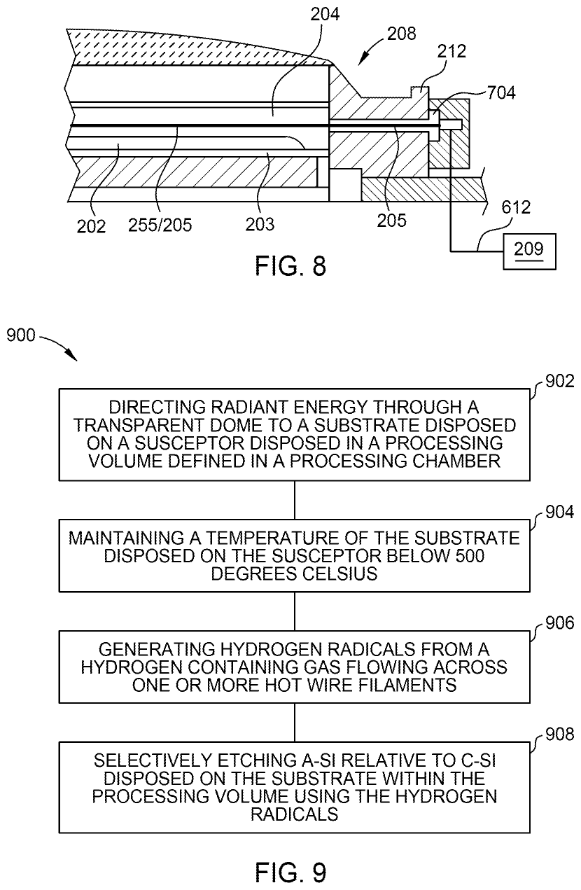

FIG. 8 is a schematic cross-sectional view of a portion of a chamber body of the EPI processing chamber of FIG. 2, according to an embodiment of the present application. More specifically, FIG. 8 exhibits a cross-sectional view of the connections of the hot wire filament array 255 described and shown in FIG. 7. FIG. 8 depicts the hot wire filament array 255 disposed over the substrate 202 in the processing volume 204 and extending through the chamber body 212. Each hot wire filament 205 of the hot wire filament array 255 connects to the leads 612 connecting to the power source 209 via the sealing connector 704.

FIG. 9 is a block diagram of a method 900 for processing a substrate within a processing chamber. The processing chamber may be configured as the processing chamber 200 described above, or within another suitable processing chamber. The method 900 is particularly suitable for etching amorphous silicon (a-Si) selectively over crystalline silicon (c-Si) at temperatures below 500 degrees Celsius.

The method 900 begins at operation 902 by directing radiant energy through a transparent dome (e.g., upper window) to a substrate disposed on a susceptor disposed in a processing volume defined in a processing chamber. In one example, radiant energy is provided by the heat sources, for example lamps, provide above and/or below the susceptor.

At operation 904, a temperature of the substrate disposed on the susceptor is maintained below 500 degrees Celsius. In one example, the temperature sensors are utilized to control power provided to the upper and/or lower heat sources to control the temperature of the substrate.

At operation 906, radicals are generated from a process gas flowing across one or more hot wire filaments. In one example, hydrogen radicals are generated from a hydrogen containing gas flowing across the one or more hot wire filaments while maintaining the filament at a temperature be greater than 1500 degrees Celsius, such as between 1500 and 2400 degrees Celsius. The one or more hot wire filaments may be disposed in a gas inlet of the processing chamber and/or within the processing volume of the processing chamber.

At operation 908, an etch process is performed in the processing chamber. For example, operation 908 may etch a-Si selectively relative to c-Si disposed on the substrate within the processing volume using the hydrogen radicals. At operation 908, the etch process occurs at temperatures less than 500 degrees Celsius. In other examples, other types of radicals may be utilized to etch material disposed on the substrate other than a-Si.

In some example, creating hydrogen radicals includes forming creating hydrogen radicals within a cartridge coupled to a sidewall of the processing chamber. In other examples, creating hydrogen radicals includes forming creating hydrogen radicals above the susceptor within the processing volume. In other examples, the process gas used to create the hydrogen radicals and a main processing gas are provided to the processing chamber from inlets disposed at different elevations relative to the susceptor. In some examples, the gas used to create the hydrogen radicals and the main processing gas are coupled to different gas sources. In some examples, the gas used to create the hydrogen radicals and the main processing gas are coupled to a common gas source, wherein a ratio of the gas used to create the hydrogen radicals and the main processing gas is controllable by adjusting the flow to one or both of the gas inlet and the main processing gas inlet.

By maintaining the hot wire filament at an appropriate temperature, molecular hydrogen is dissociated into atomic hydrogen without detrimentally heating the substrate above 500 degrees Celsius. Thus, good selectivity of a-Si over c-Si may be obtained throughout the etch process without exceeding the thermal budget of the device being formed or present on the substrate.

Is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A processing chamber comprising:
a chamber body;
a transparent dome disposed on the chamber body, the chamber body and the dome partially enclosing a processing volume;
a susceptor disposed in the processing volume;
a heat source positioned to direct radiant energy through the transparent dome toward the susceptor;
a first gas inlet formed through the chamber body; and
a first hot wire filament disposed within the first gas inlet, the first hot wire filament configured to generate radicals from gas flowing through the first gas inlet into the processing volume of the processing chamber.

2. The processing chamber according to claim 1 further comprising:
a second gas inlet formed through the chamber body laterally adjacent to the first gas inlet; and
a second hot wire filament disposed within second first gas inlet, second first hot wire filament configured to heat gas flowing through the second gas inlet into the processing volume of the processing chamber.

3. The processing chamber according to claim 1, further comprising a first cartridge containing the first hot wire filament, the first cartridge replaceably insertable into the first gas inlet.

4. The processing chamber according to claim 3, wherein the first cartridge comprises:
a gas port coupled to a gas channel, the gas port exposed to an exterior of the chamber body, the gas channel configured to direct the gas flowing through first gas port across the first hot wire filament and into the processing volume.

5. The processing chamber according to claim 4, wherein the first cartridge comprises:
a first electrical connector electrically coupled to the first hot wire filament, the first electrical connector exposed to the exterior of the chamber body.

6. The processing chamber according to claim 1 further comprising:
a first primary gas port formed through the chamber body, the first primary gas port disposed at a distance relative to the dome that is different a distance that the first gas inlet is disposed from the dome.

7. The processing chamber according to claim 6, wherein the first primary gas port and the first gas inlet are coupled to different gas sources.

8. The processing chamber according to claim 6, wherein the first primary gas port and the first gas inlet are coupled to a common gas source, wherein a ratio of gas provided to the first primary gas port and the first gas inlet is controllable.

9. The processing chamber according to claim 1, wherein the chamber body further comprises:
an exhaust port formed through the chamber body in a location selected to induce flow form the first gas inlet across the susceptor in a direction generally perpendicular to a centerline of the susceptor.

10. A processing chamber comprising:
a chamber body;
a transparent dome disposed on the chamber body, the chamber body and the dome partially enclosing a processing volume;
a susceptor disposed in the processing volume;
a heat source positioned to direct radiant energy through the transparent dome toward the susceptor;
a first gas inlet formed through the chamber body; and
a hot wire filament array disposed within the processing volume between the susceptor and the dome, the hot wire filament configured to generate radicals from gas flowing from the first gas inlet within the processing volume of the processing chamber.

11. The processing chamber according to claim 10, wherein the hot wire filament array has an orientation substantially parallel to an orientation of the susceptor.

12. The processing chamber according to claim 10, wherein the hot wire filament array comprises wires arranged in a grid.

13. The processing chamber according to claim 10, wherein the hot wire filament array and the first gas inlet are spaced at a common elevation relative to a top surface of the chamber body.

14. The processing chamber according to claim 10 further comprising:
a first primary gas port formed through the chamber body, the first primary gas port disposed at a distance relative to the dome that is different a distance that the first gas inlet is disposed from the dome.

15. The processing chamber according to claim 14, wherein the first primary gas port and the first gas inlet are coupled to different gas sources.

16. The processing chamber according to claim 14, wherein the first primary gas port and the first gas inlet are coupled to a common gas source, wherein a ratio of gas provided to the first primary gas port and the first gas inlet is controllable.

17. A method for selectively etching a substrate, the method comprising:
directing radiant energy through a transparent dome to a substrate disposed on a susceptor disposed in a processing volume defined in a processing chamber;
maintaining a temperature of the substrate disposed on the susceptor below 500 degrees Celsius;
generating hydrogen radicals from a hydrogen containing gas flowing across one or more hot wire filaments; and
selectively etching a-Si relative to c-Si disposed on the substrate within the processing volume using the hydrogen radicals.

18. The method of claim 17, wherein creating hydrogen radicals further comprises:
forming creating hydrogen radicals within a cartridge coupled to a sidewall of the processing chamber.

19. The method of claim 17, wherein creating hydrogen radicals further comprises:
forming creating hydrogen radicals above the susceptor within the processing volume.

20. The method of claim 17, further comprising:
flowing a gas used to create the hydrogen radicals and a main processing gas into the processing chamber from inlets disposed at different elevations relative to the susceptor.
